(19) United States
(12) Patent Application Publication
(10) Pub. No.: US 2017/0130363 A1
(43) Pub. Date: May 11, 2017

(54) GaAs/GaAs(1-x-y)SbxNy CORE-SHELL NANOWIRES

(71) Applicant: NORTH CAROLINA A&T STATE UNIVERSITY, Greensboro, NC (US)

(72) Inventors: Shanthi Iyer, Greensboro, NC (US); Pavan Kumar Kasanaboina, Hillsboro, OR (US); Jia Li, Greensboro, NC (US)

(21) Appl. No.: 15/343,818

(22) Filed: Nov. 4, 2016

Related U.S. Application Data
(60) Provisional application No. 62/252,263, filed on Nov. 6, 2015.

(51) Int. Cl. C30B 29/42; C30B 29/68; C30B 23/00; C30B 29/62; C09K 11/74; C09K 11/75

(52) U.S. Cl. CPC C30B 29/42; C09K 11/7492; C09K 11/75; C30B 23/007; C30B 29/62; C30B 29/68; B82Y 20/00

(57) ABSTRACT

In one aspect, compositions comprising Group III-V nanowires, and methods of making such nanowires, are described herein. In some embodiments, a composition described herein comprises one or more core-shell nanowires comprising a core and a first shell surrounding or substantially surrounding the core. The core is formed from GaAs, and the first shell is formed from GaAs_{(1-x-y)}SbₓN_{y}. Additionally, x is 0.08-0.15, and y is 0.005-0.035. In some cases, x is 0.10-0.17, and/or y is 0.01-0.02. Further, the nanowires have an average emission maximum of 1.25-1.35 μm. Moreover, in some instances, the nanowires further comprise a second shell surrounding or substantially surrounding the first shell. The second shell, in some embodiments, is formed from a Group III-V material such as GaAs. For example, in some instances, the nanowires have the structure GaAs/GaAs_{(0.82-0.9)}Sb_{(0.09-0.15)}N_{(0.005-0.033)}/GaAs.

### CROSS REFERENCE TO RELATED APPLICATIONS

This application claims priority pursuant to 35 U.S.C. §119(e) to U.S. Provisional Patent Application Ser. No. 62/252,263, filed on Nov. 6, 2015, which is hereby incorporated by reference in its entirety.

### STATEMENT AS TO RIGHTS TO INVENTIONS MADE UNDER FEDERALLY SPONSORED RESEARCH OR DEVELOPMENT

This invention was made with Government support under W911NF-11-1-022 awarded by the DOD-ARMY-ARL-ARO-ARMY RESEARCH OFFICE and W911NF-15-1-0161 awarded by the DOD DA Army Materiel Command (AMC). The Government has certain rights in this invention.

### TECHNICAL FIELD

The presently disclosed subject matter relates generally to dilute nitride GaAs/GaAsSbN core-shell nanowires, to methods of growing such nanowires, and to use of such nanowires in applications such as quantum networking applications and integrated photonic circuits.

### BACKGROUND

Semiconductor nanowires have been identified as ideal candidates for a number of applications, such as nanophotonic integrated circuits, single photon emission and detection, photonic waveguides, and nanoscale photodetectors for on-chip quantum information circuits across a range of energies. In particular, wavelengths in the near infrared (NIR) region, specifically 1.3-1.55 μm, are of great interest in quantum communication wavelengths due to the low losses over fiber optic lines.

Unfortunately, preparing semiconductor nanowires having an emission wavelength maximum of 1.3-1.55 μm, and especially 1.3 μm and 1.55 μm, has been challenging, particularly when using molecular beam epitaxy (MBE) to grow nanowires from Group III-V semiconductor materials. It has been especially difficult to provide high-quality Group III-V semiconductor nanowires having an emission wavelength maximum of 1.3-1.55 μm, an acceptable external quantum yield, a substantially uniform size distribution, and a non-curved morphology. Preparing core-shell or core-shell-shell nanowires from ternary or quaternary Group III-V materials and having the foregoing properties has been particularly challenging. Accordingly, improved Group III-V semiconductor nanowires and methods of making Group III-V semiconductor nanowires are desired.

### SUMMARY

In one aspect, compositions comprising Group III-V nanowires, and methods of making such nanowires, are described herein which, in some embodiments, exhibit one or more advantages compared to some previous compositions comprising Group nanowires, and compared to some previous methods of making such nanowires. For example, in some instances, a composition described herein comprises dilute nitride core-shell Group III-V semiconductor nanowires formed by MBE, wherein the nanowires have an emission wavelength maximum of 1.2-1.6 μm, a room temperature photoluminescence (PL) quantum yield of at least 10%, a substantially uniform size distribution, and a non-curved morphology. As described further hereinbelow, the inventors of the presently described subject matter have surprisingly discovered that such nanowires can be obtained through the use of minimal nitrogen content in combination with disclosed ranges of antimony content. More specifically, the inventors of the present application have discovered that improved results can be obtained by altering a protocol for providing non-curved GaAs/GaAs₍₁₋ₓ₎Sbₓ core-shell nanowires to include a small amount of nitrogen in the GaAs₍₁₋ₓ₎Sbₓ shell. It is possible to obtain GaAs/GaAs₍₁₋ₓ₎Sbₓ nanowires having an average emission of about 1.3 μm (e.g., with the use of about 26% Sb); however, such nanowires have a curved morphology beyond a certain length and/or aspect ratio, significantly reducing the usefulness of these nanowires in various optical applications. The inventors of the present application have discovered that the amount of nitrogen used in embodiments of nanowires described herein can be selected to be minimally sufficient to provide a desired luminescence emission shift as compared to GaAs/GaAs₍₁₋ₓ₎Sbₓ nanowires, while also avoiding curved morphologies. Not intending to be bound by theory, it is believed that using a minimal amount of nitrogen avoids negative effects on growth dynamics and nanowire structure believed to be caused by the use of nitrogen, particularly in an MBE process. The amounts of nitrogen, antimony, and arsenic in quaternary Group III-V core-shell nanowires described herein has been discovered to provide advantageous nanowire growth conditions for obtaining desirable nanowire optical properties as well as desirable nanowire morphologies. In particular, GaAs/GaAs_{(1-x-y)}SbₓN_{y} core-shell nanowires described herein can have an emission wavelength maximum of near 1.3-1.55 μm, while also exhibiting a non-curved morphology, including at sizes and aspect ratios described further hereinbelow.

In some exemplary embodiments, a composition described herein comprises one or more core-shell nanowires comprising a core and a first shell surrounding or substantially surrounding the core. The core is formed from GaAs, and the first shell is formed from GaAs_{(1-x-y)}SbₓN_{y}. Additionally, x is 0.08-0.15, and y is 0.005-0.035. In some cases, x is 0.10-0.17, and/or y is 0.01-0.02. Further, the nanowires have an average emission maximum of 1.25-1.35 μm at room temperature (23° C.). Moreover, in some instances, the nanowires further comprise a second shell surrounding or substantially surrounding the first shell. The second shell, in some embodiments, is formed from a Group III-V material such as GaAs. For example, in some instances, the nanowires have the structure GaAs/GaAs_{(0.82-0.0.9)}Sb_{(0.09-0.15)}N_{(0.005-0.033)}/GaAs. Core-shell nanowires described herein may also be annealed.

In addition, in some embodiments, the nanowires of a composition described herein have an average length of at least 2 μm and/or an aspect ratio of at least 10, as well as a straight or substantially straight morphology. For instance, in some cases, the nanowires have an average length of at least 2 μm, an average aspect ratio of at least 10, and an average radius of curvature of at least 5 times the average length of the core-shell nanowires.

Moreover, in some cases, a composition described herein comprises an array of core-shell nanowires, wherein the core-shell nanowires have the structural properties and/or the optical properties described hereinabove. For instance, in some embodiments, a composition described herein comprises an array of a plurality of core-shell nanowires, each of the core-shell nanowires comprising a core and a first shell surrounding or substantially surrounding the core, wherein the core is formed from GaAs, wherein the first shell is formed from GaAs_{(1-x-y)}SbₓSbₓN_{y}, wherein x is 0.08-0.15, wherein y is 0.005-0.035, and wherein the nanowires have an average emission maximum of 1.25-1.35 μm at room temperature. Additionally, in some cases, the array of core-shell nanowires is an ordered array. Moreover, in some embodiments, the core-shell nanowires of an array described herein are aligned. For example, in some cases, the core-shell nanowires are vertically aligned or substantially vertically aligned, relative to a substrate on which the nanowires are disposed or grown. Additionally, in some embodiments, the array of core-shell nanowires has a high nanowire density.

These and other embodiments are described in greater detail in the detailed description which follows. An object of the presently disclosed subject matter having been stated hereinabove, and which is achieved in whole or in part by the presently disclosed subject matter, other objects will become evident as the description proceeds when taken in connection with the accompanying drawings as best described hereinbelow.

### BRIEF DESCRIPTION OF THE DRAWINGS

FIG. 1A illustrates a scanning electron microscope (SEM) image of an array of core-shell nanowires according to one embodiment described herein.

FIG. 1B illustrates SEM images of individual core-shell nanowires according to some embodiments described herein.

FIG. 2A illustrates a scanning transmission electron microscope (STEM) image of a core-shell nanowire according to one embodiment described herein.

FIG. 2B illustrates an STEM image and an energy dispersive x-ray spectroscopy (EDS) profile of a core-shell nanowire according to one embodiment described herein.

FIG. 2C illustrates a high resolution transmission electron microscope (HRTEM) image of a core-shell nanowire according to one embodiment described herein.

FIG. 2D illustrates a selected area electron diffraction (SAED) pattern of a core-shell nanowire according to one embodiment described herein.

FIG. 3A illustrates x-ray diffraction (XRD) patterns of core-shell nanowires and comparative nanowires according to some embodiments described herein.

FIG. 3B illustrates XRD data of core-shell nanowires and comparative nanowires according to some embodiments described herein.

FIG. 3C illustrates XRD data of core-shell nanowires and comparative nanowires according to some embodiments described herein.

FIG. 4A illustrates photoluminescence spectra of core-shell nanowires and comparative nanowires according to some embodiments described herein.

FIG. 4B illustrates photoluminescence spectra of core-shell nanowires according to some embodiments described herein.

FIG. 5 illustrates Raman spectra of core-shell nanowires and comparative nanowires according to some embodiments described herein.

FIG. 6A illustrates a transmission electron microscopy (TEM) image of a core-shell nanowire according to one embodiment described herein.

FIG. 6B illustrates an HRTEM image of a core-shell nanowire according to one embodiment described herein.

FIG. 7 illustrates photoluminescence spectra of core-shell nanowires according to some embodiments described herein.

FIG. 8A illustrates photoluminescence data for core-shell nanowires according to some embodiments described herein.

FIG. 8B illustrates photoluminescence data for core-shell nanowires according to some embodiments described herein.

FIG. 9 illustrates Raman spectra of core-shell nanowires and comparative nanowires according to some embodiments described herein.

FIG. 10A illustrates current-voltage (I-V) curves for core-shell nanowires according to some embodiments described herein.

FIG. 10B illustrates a plot of Schottky barrier height for core-shell nanowires according to some embodiments described herein.

### DETAILED DESCRIPTION

The presently disclosed subject matter will now be described more fully. The presently disclosed subject matter can, however, be embodied in different forms and should not be construed as limited to the embodiments set forth herein below and in the accompanying Examples. Rather, these embodiments are provided so that this disclosure will be thorough and complete, and will fully convey the scope of the embodiments to those skilled in the art.

All references listed herein, including but not limited to all patents, patent applications and publications thereof, and scientific journal articles, are incorporated herein by reference in their entireties to the extent that they supplement, explain, provide a background for, or teach methodology, techniques, and/or compositions employed herein.

### I. DEFINITIONS

While the following terms are believed to be well understood by one of ordinary skill in the art, the following definitions are set forth to facilitate explanation of the presently disclosed subject matter.

Unless defined otherwise, all technical and scientific terms used herein have the same meaning as commonly understood to one of ordinary skill in the art to which the presently disclosed subject matter belongs.

Following long-standing patent law convention, the terms “a” and “an” refer to “one or more” when used in this application, including the claims.

The term “and/or” when used in describing two or more items or conditions, refers to situations where all named items or conditions are present or applicable, or to situations wherein only one (or less than all) of the items or conditions is present or applicable.

The use of the term “or” in the claims is used to mean “and/or” unless explicitly indicated to refer to alternatives only or the alternatives are mutually exclusive, although the disclosure supports a definition that refers to only alternatives and “and/or.”

As used herein “another” can mean at least a second or more.

The term “comprising”, which is synonymous with “including,” “containing,” or “characterized by” is inclusive or open-ended and does not exclude additional, unrecited elements or method steps. “Comprising” is a term of art used in claim language which means that the named elements are essential, but other elements can be added and still form a construct within the scope of the claim.

As used herein, the phrase “consisting of” excludes any element, step, or ingredient not specified in the claim. When the phrase “consists of” appears in a clause of the body of a claim, rather than immediately following the preamble, it limits only the element set forth in that clause; other elements are not excluded from the claim as a whole.

As used herein, the phrase “consisting essentially of” limits the scope of a claim to the specified materials or steps, plus those that do not materially affect the basic and novel characteristic(s) of the claimed subject matter.

With respect to the terms “comprising”, “consisting of”, and “consisting essentially of”, where one of these three terms is used herein, the presently disclosed subject matter can include the use of either of the other two terms.

As used herein, the term “about”, when referring to a value is meant to encompass variations of in one example ±20% or ±10%, in another example ±5%, in another example ±1%, and in still another example ±0.1% from the specified amount, as such variations are appropriate to practice the disclosed inventions.

In addition, all ranges disclosed herein are to be understood to encompass any and all subranges subsumed therein. For example, a stated range of “1.0 to 10.0” should be considered to include any and all subranges beginning with a minimum value of 1.0 or more and ending with a maximum value of 10.0 or less, e.g., 1.0 to 5.3, or 4.7 to 10.0, or 3.6 to 7.9.

All ranges disclosed herein are also to be considered to include the end points of the range, unless expressly stated otherwise. For example, a range of “between 5 and 10”, “from 5 to 10” or “5-10” should generally be considered to include the end points 5 and 10.

Further, when the phrase “up to” is used in connection with an amount or quantity, it is to be understood that the amount is at least a detectable amount or quantity. For example, a material present in an amount “up to” a specified amount can be present from a detectable amount and up to and including the specified amount.

As used herein, the phrase “substantially vertically aligned” refers to an orientation of a plurality of anisotropic objects (e.g., nanowires) in a population of the objects, wherein at least about 60 percent, at least about 70 percent, at least about 80 percent, or at least about 90 percent of the objects (e.g., nanowires) of the population have a vertical or substantially vertical orientation. A “vertical orientation” refers to an orientation wherein the long axis of an anisotropic object (e.g., a nanowire) forms an angle (θ) of less than about 30 degrees, less than about 15 degrees, or less than about 10 degrees with a vertical line or direction described herein.

Similarly, anisotropic objects that are “substantially aligned” without reference to a specific direction (e.g., a vertical direction) of alignment are aligned with reference to an average orientation or direction of alignment of the population of anisotropic objects. Further, at least about 60 percent, at least about 70 percent, at least about 80 percent, or at least about 90 percent of the objects (e.g., nanowires) of the population have an orientation or alignment wherein the long axis of the anisotropic object (e.g., a nanowire) forms an angle (θ) of less than about 30 degrees, less than about 15 degrees, or less than about 10 degrees with an average orientation or direction described hereinabove.

An “array” of objects (e.g., nanowires), as used herein, refers to a group of the objects on a surface. An “ordered” array refers to an array in which the arrangement of the objects within the array follows a pattern or substantially follows a pattern (i.e., within 20%, within 10%, or within 5% deviation from the pattern). For example, the objects of an “ordered” array can be arranged in regularly spaced rows and columns. The “density” of an array refers to the percentage of the area of the surface that is occupied by the objects of the array (as opposed to being vacant or occupied by some other item).

### II. COMPOSITIONS COMPRISING CORE-SHELL NANOWIRES

In one aspect, compositions comprising one or more core-shell nanowires are described herein. The core-shell nanowires comprise a core and a first shell surrounding or substantially surrounding the core. The core is formed from GaAs, and the first shell is formed from GaAs_{(1-x-y)}SbₓN_{y}, wherein x is 0.08-0.15 or 0.10-0.17, and y is 0.005-0.035 or 0.01-0.02. Additionally, in some cases, the nanowires have an average emission maximum of 1.25-1.35 μm, including at room temperature. Moreover, in some instances, the nanowires further comprise a second shell surrounding or substantially surrounding the first shell. In some such embodiments, the second shell is formed from GaAs. Therefore, in some cases, the core-shell nanowires of a composition described herein have the structure GaAs/GaAs_{(0.82-0.9)}Sb_{(0.09-0.15)}N_{(0.005-0.033)}/GaAs.

Moreover, in some cases, a composition described herein comprises an array of core-shell nanowires. For example, in some instances, a composition described herein comprises an array of a plurality of core-shell nanowires, the core-shell nanowires comprising a core and a first shell surrounding or substantially surrounding the core, wherein the core is formed from GaAs, wherein the first shell is formed from GaAs_{(1-x-y)}SbₓN_{y}, wherein x is 0.08-0.15, wherein y is 0.005-0.035, and wherein the nanowires have an average emission maximum of 1.25-1.35 μm at room temperature. In some cases, the array is an ordered array, such as an array in which the core-shell nanowires are arranged in regularly spaced rows and columns. Further, in some embodiments, the core-shell nanowires of an array described herein are aligned. For example, in some cases, the core-shell nanowires are vertically aligned or substantially vertically aligned, where the “vertical” direction corresponds to a direction perpendicular to the surface of the substrate on which the nanowires are disposed. Additionally, in some embodiments, the array of core-shell nanowires has a high nanowire density. For instance, in some embodiments, the core-shell nanowires occupy at least about 40%, at least about 50%, at least about 60%, at least about 70%, at least about 80%, or at least about 90% of the surface of the substrate on which the nanowires are disposed. In some cases, the core-shell nanowires occupy 40-100%, 40-90%, 40-80%, 40-70%, 50-100%, 50-90%, 50-80%, 50-70%, 60-100%, 60-90%, 60-80%, 70-100%, or 70-90% of the surface of the substrate on which the nanowires are disposed.

Specific components of core-shell nanowires described herein will now be more particularly described. Core-shell nanowires described herein comprise a core, the core being formed from GaAs. As understood by one of ordinary skill in the art, a “core” of a core-shell nanowire can itself be a nanowire, where a “nanowire” is understood to refer to an anisotropic material or particle having a diameter (d) or size in two dimensions (e.g., height and width) of 1-1000 nm, 1-500 nm, or 1-100 nm, and an aspect ratio of at least 10, at least 50, or at least 100. It is further to be understood that a nanowire described herein can be cylindrical or substantially cylindrical. A nanowire described herein can also be faceted, as opposed to having a continuously curved circumference.

The core of a nanowire described herein can have any size and shape not inconsistent with the objectives of the present disclosure. In some embodiments, the core has an average diameter (or height or width) greater than the Bohr diameter of GaAs. For example, in some cases, the core has an average diameter of 50-110 nm or 70-90 nm. Thus, in some embodiments, the core does not have a diameter (or height or width) consistent with quantum confinement of a charge carrier (specifically, an electron or a hole, or an electron-hole pair or exciton) within the core in a diametric (or height or width) direction.

Core-shell nanowires described herein also comprise a first shell surrounding (or covering or “overcoating”) or substantially surrounding (or covering or “overcoating”) the core of the nanowires. As understood by one of ordinary skill in the art, a first shell that “surrounds” or “substantially surrounds” (or “covers” or “substantially covers” or “overcoats” or “substantially overcoats”) the core can surround or substantially surround (or cover or substantially cover or overcoat or substantially overcoat) the circumference of the core, such that the first shell surrounds or substantially surrounds (or covers or overcoats) the core radially. The first shell may also surround or substantially surround (or cover or substantially cover or overcoat or substantially overcoat) the core on the ends or faces of the core longitudinally (i.e., at the ends of the “length” or “long dimension” of the core). Additionally, the first shell can surround (or cover or overcoat) at least about 80%, at least about 85%, at least about 90%, at least about 95%, at least about 98%, or at least about 99% of the relevant surface or surfaces of the core, based on area. Thus, in some cases, the first shell completely or substantially completely surrounds, covers, or overcoats the core.

As described above, the first shell is formed from GaAs_{(1-x-y)}SbₓN_{y}. It is to be understood that the value of x (i.e., the antimony content) is determined according to scanning transmission electron microscope (STEM) energy-dispersive x-ray spectroscopy (EDS) analysis. It is further to be understood that the value of y (i.e., the nitrogen content) is determined according to Equation (1) below:

y=(A+B)/2 Equation (1),

where A is the atom flux of nitrogen used to form the first shell in an MBE process (e.g., A=0.017 for a nitrogen flux of 1.7 atom %), and B is the atom percent of nitrogen determined based on the red shift in emission when comparing the peak emission of GaAs_{(1-x-y)}SbₓN_{y} to the peak emission of GaAs₍₁₋ₓ₎Sbₓ for a given value of x, in accordance with Harmand et al., Chapter 15, “GaNAsSb Alloy and Its Potential for Device Applications,” in Dilute Nitride Semiconductors, edited by M. Henini, Elsevier Ltd., p. 480. Specifically, regarding the value of B, for each 173 meV reduction (i.e., red shift) in photoluminescence (PL) peak emission at 4 Kelvin (K), the amount of nitrogen included in the composition is taken to be 1% (i.e., y=0.01). Thus, as one example, if 1.7 atom % flux of nitrogen is used to prepare a first shell in which x=0.10 (i.e., the Sb content is 10%), and if the measured red shift in the PL emission peak for GaAs_{(1-0.10-y)}Sb_{0.10}N_{y} is 190 meV compared to GaAs_{0.9}Sb_{0.10}, then the value of y is taken to be (0.017+0.011)/2=0.014, corresponding to 1.4% nitrogen content, since (190 meV)/(173 meV) is equal to 1.1, corresponding to a B value associated with 1.1% nitrogen content.

The first shell of a core-shell nanowire described herein can have any thickness not inconsistent with the objectives of the present disclosure. In some cases, the first shell has an average thickness greater than the Bohr diameter of GaAs_{(1-x-y)}SbₓN_{y} (which may be about 10 nm, in some cases). For instance, in some embodiments, the first shell has an average thickness of 30-90 nm or 50-80 nm. Thus, in some cases, the first shell does not have a thickness consistent with quantum confinement of a charge carrier (specifically, an electron or a hole, or an electron-hole pair or exciton) within the first shell in a direction corresponding to the thickness of the first shell. Alternatively, in other instances, the first shell has an average thickness less than or equal to the Bohr diameter of GaAs_{(1-x-y)}SbₓN_{y}. For example, in some such embodiments, the first shell has an average thickness of less than 10 nm. As understood by one of ordinary skill in the art, such a first shell could exhibit quantum confinement of a charge carrier or exciton.

Core-shell nanowires described herein, in some cases, further comprise a second shell surrounding (or covering or overcoating) or substantially surrounding (or covering or overcoating) the first shell of the nanowires. As understood by one of ordinary skill in the art, a second shell that “surrounds” or “substantially surrounds” (or “covers” or “substantially covers” or “overcoats” or “substantially overcoats”) the first shell can surround or substantially surround (or cover or substantially cover or overcoat or substantially overcoat) the circumference of the first shell, such that the second shell surrounds or substantially surrounds (or covers or overcoats) the first shell radially. The second shell may also surround or substantially surround (or cover or substantially cover or overcoat or substantially overcoat) the first shell on the ends or faces of the first shell longitudinally (i.e., at the ends of the “length” or “long dimension” of the first shell). Additionally, the second shell can surround (or cover or overcoat) at least about 80%, at least about 85%, at least about 90%, at least about 95%, at least about 98%, or at least about 99% of the relevant surface or surfaces of the first shell, based on area. Thus, in some cases, the second shell completely or substantially completely surrounds, covers, or overcoats the first shell.

The second shell can be formed from any material not inconsistent with the objectives of the present disclosure. In some cases, the second shell is formed from a Group III-V material. For instance, in some embodiments, the second shell is formed from GaAs. Moreover, the second shell can have any thickness not inconsistent with the objectives of the present disclosure. In some cases, the second shell has an average thickness greater than the Bohr diameter of the material used to form the second shell (e.g., GaAs). In other instances, the second shell has an average thickness less than or equal to the Bohr diameter of the material used to form the second shell (e.g., GaAs). In some embodiments, the second shell has an average thickness of at least 5 nm or at least 10 nm. In some cases, the second shell has an average thickness of 10-30 nm. Other thicknesses are also possible.

Additionally, in some cases, the physical structures of the first shell and the second shell are selected to obtain a desired electronic band structure within the core-shell nanowire. For example, in some instances, the composition and/or physical dimensions of the first shell and the second shell of a core-shell nanowire described herein are selected such that the first shell and the second shell have a Type I band offset structure. In such a structure, as understood by one of ordinary skill in the art, the second shell has a higher energy bandgap than the first shell, and the conduction band of the second shell is higher energy (compared to vacuum) than the conduction band of the first shell, and the valence band of the second shell is lower energy (compared to vacuum) than the valence band of the first shell. Other band structures are also possible.

It is further to be understood that core-shell nanowires described herein can have any total dimensions not inconsistent with the objectives of the present disclosure. For example, in some cases, the core-shell nanowires have an average diameter of 100-500 nm, 100-300 nm, 100-200 nm, 150-500 nm, 150-300 nm, or 150-250 nm. Further, in some embodiments, the nanowires have an average length of at least 2 μm, at least 5 μm, at least 10 μm, or at least 50 μm. In some instances, the nanowires have an average length of 2-100 μm, 2-50 μm, 2-20 μm, 2-10 μm, 5-100 μm, 5-50 μm, 5-20 μm, 5-10 μm, 10-100 μm, or 10-50 μm. Additionally, such nanowires can also have an aspect ratio of at least 10, at least 20, at least 50, at least 100, or at least 1000. In some cases, core-shell nanowires described herein have an aspect ratio of 10-5000, 10-1000, 10-500, 10-100, 10-50, 10-20, 20-5000, 20-1000, 20-500, 20-100, 20-50, 50-5000, 50-1000, 50-500, 50-100, 100-5000, 100-1000, or 100-500.

Moreover, in some embodiments, core-shell nanowires described herein having a high aspect ratio also have a straight or substantially straight morphology, as opposed to a curved morphology. In some instances, the core-shell nanowires have an average radius of curvature that is at least 5 times the average length of the core-shell nanowires. In some cases, the core-shell nanowires have an average radius of curvature of at least 10, at least 20, at least 50, at least 100, at least 500, or at least 1000 times the average length of the nanowires. In some embodiments, the core-shell nanowires have an average radius of curvature that is 5-1000, 5-500, 5-100, 5-50, 10-1000, 10-500, 10-100, 10-50, 50-1000, 50-500, or 50-100 times the average length of the nanowires.

Additionally, core-shell nanowires can have any combination of sizes and shapes described hereinabove and not inconsistent with the objectives of the present disclosure. For example, in some cases, the nanowires have an average diameter of 150-250 nm, an average length of at least 2 μm, an average aspect ratio of at least 10, and an average radius of curvature of at least 5 times the average length of the core-shell nanowires. Other combinations of sizes and shapes are also possible.

Moreover, in some embodiments, an array or other population of core-shell nanowires described herein is homogeneous or substantially homogeneous in size, shape, and/or composition. For instance, in some cases, the nanowires of a population or array described herein have a size distribution (in diameter, length, and/or aspect ratio) of 15% or less, 10% or less, or 5% or less, where the percentage is based on two standard deviations from a mean size. Similarly, in some cases, the full width at half maximum (FWHM) of the peak photoluminescence (PL) emission of a population or array of nanowires differs from the FWHM of the peak PL emission of a single nanowire of the population or array by less than 20 meV, less than 15 meV, less than 10 meV, or less than 5 meV.

Core-shell nanowires described herein can also exhibit a variety of optical and/or luminescent properties. For example, in some cases, the nanowires have a room temperature (23° C.) photoluminescence (PL) quantum yield (QY) of at least 10%, at least 15%, at least 20%, at least 30%, or at least 40%. In some instances, the nanowires have a room temperature PL QY of 10-60%, 10-50%, 10-40%, 10-30%, 10-20%, 15-60%, 15-50%, 15-40%, 15-30%, 20-60%, 20-50%, 20-30%, 30-60%, or 30-50%. Moreover, not intending to be bound by theory, it is believed that the PL of a core-shell nanowire described herein, in some cases, can be emitted from the first shell of the core-shell nanowire, as opposed to being emitted from the core or the second shell.

As described further hereinbelow, core-shell nanowires described herein can be made in any manner not inconsistent with the objectives of the present disclosure. The core-shell nanowires may especially advantageously be made by molecular beam epitaxy (MBE), including solid source plasma assisted MBE.

### EXAMPLES

The following Examples have been included to provide guidance to one of ordinary skill in the art for practicing representative embodiments of the presently disclosed subject matter. In light of the present disclosure and the general level of skill in the art, those of skill can appreciate that the following Examples are intended to be exemplary only and that numerous changes, modifications, and alterations can be employed without departing from the scope of the presently disclosed subject matter.

### Summary of Results

Core-shell nanowires described herein offer various advantages compared to other semiconductor structures. For example, the so-called “one-dimensional” (1D) structure of nanowires offer flexibility in band-gap engineering, material design architecture, and a wide choice of substrates, which have made nanowires an attractive candidate for a variety of device applications in the nanoscale. Due to the small nanowire (NW) footprint on the substrate, the substrate can accommodate large lattice and thermal expansion coefficient mismatch between the NW and the substrate. NWs thus enable the integration of different material combinations on a wide range of substrates. As the diameter of NW is constrained (typically to several tens of nanometers), and the length is not constrained (typically to several micrometers), charge carriers generated within the NW are confined in two dimensions, while the carriers freely propagate in the third (long) dimension of the NW. This manifests in a high density of electronic states, leading to electrical, optical and magnetic properties quite different from bulk and thin film counterparts. Additionally, the presence of a large surface-to-volume ratio leads to lowering of the barrier for chemical reaction and higher defect tolerance.

The 1D architecture of nanowires also enables implementation of different architectures, including but not limited to axial inserts and core-shell heterostructured configurations. Core-shell structured nanowires, also referred to as radial heterostructures, have several additional advantages over axial heterostructures in growth, design, optical properties and material composition aspects. For example, the core-shell configuration presents a distinct pathway for decoupling of vertical light absorption and radial carrier separation. In addition, the core-shell configuration increases lattice mismatch tolerance compared to axial heterostructured nanowires, in which the optical absorption and charge separation share the same region, thereby limiting charge separation to this small region.

The 1D geometry of nanowires offers advantages over the thin films in terms of better stress-strain management, increased defect tolerance, reduced reflection, enhanced light trapping and improved band gap tuning. Separately, NW geometry enhances the light-matter interaction through better light trapping and improved antireflection characteristics compared to its thin film counterpart. Moreover, the use of NWs facilitates the assembly of multifunction components on the same substrate and thereby hybrid integration of driver electronics and detectors on the same chip. Such systems can be used in parallel with existing sensing technologies in areas such as chemical/biological sensing, environmental monitoring, imaging, and information processing. For example, photonic circuits can be assembled from a collection of nanowire elements that offer various functions, such as light creation, routing, and detection. Further, NW arrays are suited to meet the demands of the next generation electronic and optoelectronic devices, such as light emitting diodes, solar cells, photodetectors, lasers, and gas sensors, and imaging, with high prospects for improving detection limits and spatial resolution.

Since Group III-V semiconductor materials exhibit direct band gaps with large carrier mobility, they are good candidates for realization of optoelectronic devices. By tuning the bandgap of the III-V compound semiconductors, desired emission wavelengths and photodetection that are suitable for specific applications can be obtained. In particular, wavelengths of 1.3-1.55 μm are of great interest for photonic bandgap arrays and quantum data communication applications, which call for nanoscale sources and detectors.

As described hereinabove, band gap tuning of nanowires comprising dilute nitride GaAsSbN is disclosed. Independent tuning of valence band and conduction band offsets was achieved by varying the amounts of antimony and nitrogen, respectively. In some embodiments, room temperature emission of 1.3 μm was demonstrated at lower Sb composition (10 at. % or 10 atomic percent) with a straight nanowire morphology. As demonstrated, the photoluminescence (PL) spectrum of a single nanowire was replicated in ensemble nanowires (or arrays of nanowires), demonstrating good compositional homogeneity of the latter.

Additionally, as shown herein, dilute nitride GaAs/GaAsSbN/GaAs core-multi shell nanowires (also written as “GaAs/GaAs_{(1-x-y)}SbₓN_{y}/GaAs core-shell nanowires”) can be annealed to further improve their structural and optical quality. In some cases, increasing the annealing temperature from about 650° C. to about 750° C. increases the intensity of band to band emission by 5-fold with a corresponding decrease in the full width at half maximum (FWHM) of the PL peak, while at the same time the intensity of the N-related defect peak at 0.85 eV gradually diminishes. Not intending to be bound by theory, a corresponding increase in the Schottky barrier height from 0.1 to 0.4 eV suggests an efficient annihilation of point defects. The effective annihilation of defects and observation of room temperature PL, inter alia, demonstrate the advantage of the nanowire configuration for this dilute nitride system in nanoscale optoelectronic devices for quantum information science and nanoscale detectors in the telecommunication wavelength region.

The successful growth of dilute nitride GaAs/GaAsSbN/GaAs core-multi shell nanowires using plasma assisted MBE is disclosed herein. Additionally, conditions for the growth of such GaAs/GaAsSbN/GaAs core-multi shell nanowires are provided. In some embodiments, the prepared nanowires are substantially vertical and/or substantially aligned. The μ-PL measurements revealed red shifts as well as broadening of the spectra. The band gap shifted to 1.3 μm at lower Sb content of 10 at. % in GaAsSbN system as compared to 26 at. % in GaAsSb system. XRD analysis revealed close lattice matching of GaAsSbN with GaAs and vertical nanowires. Without being bound by theory, a red shift of 7 cm⁻¹ in the Raman spectrum and associated symmetric line shapes exhibited by these nanowires are attributed to phonon localization at point defects. In addition to band edge emission, as-grown nanowires exhibit a shoulder peak at ˜0.85 eV, identified to arise from band tail states. To reduce or even annihilate N-induced defects, the nanowires were ex situ annealed by rapid thermal annealing (RTA) in a nitrogen atmosphere. Experiments using different temperatures of annealing (650° C., 700° C. and 750° C.) for about 30 seconds are summarized. Increased annealing temperature corresponded to: a five-fold improvement in the intensity of band to band emission; a corresponding decrease in the FWHM of the PL peak; and a disappearance of the intensity of the peak at 0.85 eV attributed to a nitrogen-related defect. Annihilation of the N-related defects was also corroborated by the recovery of the Raman shift and the increase in the Schottky barrier height from 0.1 to 0.4 eV. A significant reduction in the temperature-induced energy shift in the annealed nanowires was observed and, without being bound by theory, is attributed to annihilation of band tail states and weak temperature dependence of nitrogen-related localized states.

The observation of a room temperature PL signal in the 1.3 μm region shows that adding nitrogen (N) to GaAsSb is one route to efficient nanoscale light emitters with reduced temperature sensitivity.

The absorption properties of a NW array are a function of distance between nanowires. Therefore, position controlled growth of a patterned array of nanowires can be important for realization of efficient devices. The growth of patterned nanowires on a Si substrate as described herein included pre-patterning of the substrate. As disclosed herein, an electron beam lithography (EBL) tool was used for pre-patterning, and the process parameters such as beam current, dose time, reactive ion etching (RIE) duration were selected to provide desired growth conditions.

Characterization Techniques and Instrument Information

The nanowires prepared according to the methods disclosed herein were ex situ characterized by scanning electron microscope (SEM) for morphology. Transmission electron microscopy (TEM), selected area electron diffraction (SAED) pattern, and high-resolution TEM (HRTEM) were used to determine structural information, and x-ray diffraction (XRD) was used to estimate the strain. Energy dispersive x-ray spectroscopy (EDS) attached to SEM was used for compositional analysis, including as described above. Optical characterization included μ-PL spectroscopy and Raman spectroscopy.

Scanning Electron Microscopy.

All the samples were scanned using a Carl Zeiss Auriga-BU FIB FESEM Microscope (Carl Zeiss Microscopy, Thornwood, N.Y., USA) equipped with Bruker Energy Dispersive Spectrometer (EDS), (Bruker, Harvard, Mass., USA). The samples were first mounted on aluminum stubs using a double sided carbon tape. SEM imaging was used to determine the overall MBE growth outcomes, as well as to measure the length, radii and yield of vertically aligned nanowires. For plane view imaging and for moderate tilts (up to 45°), a flat stub was used. It was not necessary to apply any additional conductive paste or tape, since the Si substrate provided sufficient electrical contact to ground the sample. To get full 90° side views of the nanowires, 45° SEM stubs were used to increase the range of imaging angles. Typical accelerating voltages of 5-10 kV and working distances between 4-8 mm were used. For compositional analysis, EDS with operating voltages of 15-20 kV were used.

Transmission Electron Microscopy.

The bright-field TEM, SAED, and high-resolution TEM (HRTEM) were characterized on a JEOL 2010F microscope operated at 200 kV. The sample preparation consisted of sonication of the nanowires in acetone, as the first step, to detach nanowires from the Si substrate. Then a small drop of colloidal suspension is pipetted onto a TEM grid and simply allowed to dry at room temperature. The grid with nanowires is then directly observed in a TEM once the medium is evaporated. STEM analysis was performed on a probe aberration-corrected FEI Titan G2 system operated at 200 kV.

X-Ray Diffraction.

XRD scans were performed using a Bruker D8 Discover instrument with a DaVinci diffractometer in the standard Bragg-Brentano para-focusing configuration to ascertain the orientation and strain effects in the nanowires. X-rays from the Cu Kα source were not filtered and thus contained both Kα1 and Kα2 components.

Micro-Photoluminescence Spectroscopy.

The μ-PL measurements were conducted in a low vibration closed cycle optical cryostat from Montana Cryostation with the sample chamber extended away from the cryostat. The sample chamber was interfaced with a fiber-coupled confocal microscope from Horiba Jobin Yvon, Inc., with a 633 nm He—Ne laser as the excitation source. The PL signal from the sample was then dispersed using a 0.32 m double-grating monochromator with liquid nitrogen cooled InGaAs detector for detection using conventional lock-in techniques. An Olympus IR 50× lens was used to focus the laser on the nanowires. The variations of PL characteristics were studied in the 4-300 K temperature range.

Raman Spectroscopy.

Raman spectroscopy was carried out at room temperature to determine the vibrational characteristics and hence quality of, the nanowires in a Horiba Jobin Yvon LabRam ARAMIS Raman microscope using a He—Ne laser with 633 nm excitation wavelength. The Raman signal was detected using a multichannel air-cooled charge-coupled device. The instrument was calibrated using a standard Si sample to observe a peak at 520 cm⁻¹.

Rapid Thermal Annealing.

All the nanowires were annealed in N₂ ambient using a Jipelec JetFirst 100 RTA for 30 sec. A ramp rate of 50° C./sec and N₂ flow of 1200 sccm were maintained during annealing.

I-V Measurements.

For I-V measurements on ensemble of nanowires, the array of nanowires was initially spun with polymethylmethacrylate (PMMA), which was plasma etched to 200 nm in order to expose the tips of the nanowires. The top contact was Ti(50 nm)/Au(200 nm) while the back contact was Ti(200 nm). To avoid possible short circuits at the sample edges, the top contacts were deposited using a shadow mask consisting of an array of 1 mm diameter circular apertures to produce discrete contact pads and then a contact on the bottom of the substrate was deposited. Both these contacts were made by using Kurt J Lesker PVD75 electron beam evaporator system. Electrical measurements were performed at room temperature using a Keithley 4200 characterization system by a two probe method.

Molecular Beam Epitaxy.

Molecular beam epitaxy (MBE) was used for self-catalyzed growth of the nanowires disclosed herein. A Veeco EPI 930 solid source MBE (Veeco, Inc., Plainview, N.Y., USA) was used. The EPI 930 MBE consists of 5 Knudsen effusion cells, one SUMO cell, two valved crackers and a UNI-Bulb plasma nitrogen source. The MBE system is dedicated to dilute nitride mixed As—Sb system. The Group III elements include Ga, In and Al and Group V elements included N, As and Sb. For Ga source, a SUMO cell was used which uses dual filament in a hot lip configuration. The majority of the power is fed to the tip filament and thus the tip operated at a higher temperature than the primary filament. In this type of hot lipped operation, oval defects are reduced as it reduces Ga droplet formation in the crucible. Valved cracker cells were used for Group V species (As and Sb), permitting controlled amounts of tetramers, dimers and monomers by varying the cracker temperature. The automated needle valve positioners present in these cells provided accurate control of the flux. The substrate temperature was read by the pyrometer and controlled using a thermocouple attached to the back side of the sample holder.

Preparation of Substrate for Growing an Array of Core-Shell Nanowires

In one exemplary embodiment, an Electron Beam Lithography (EBL) system was used to make a nanoscale array of holes in an oxide layer of a silicon substrate for the growth of patterned array of nanowires. As understood by one of ordinary skill in the art, in EBL, a high energy focused electron beam is used to make a desired pattern on a resist which is subsequently transferred to an oxide layer using chemical or RIE. Since EBL uses a software design file to write features on a resist, it is easy to modify the feature properties (e.g., hole diameter, distance between holes and number of holes). The focused electron beam diameter limits the minimum line width that can be achieved on the resist. Feature sizes of <10 nm can be achieved. In this example, a positive photo resist was used.

Specifically, a PMMA 950K photo resist layer was spun onto a 15 nm SiO₂/Si(111) substrate at 3000 rpm for 40 s followed by hot plate bake at 180° C. for 120 s. An approximate PMMA layer thickness of ˜120 nm was achieved. The sample was then loaded into an Elionix ELS-7500 EX EBL system. A pre-designed computer aided design (CAD) file was loaded into EBL system to write the desired features onto the PMMA resist layer. A high voltage of 50 keV and 50 pA beam current were used during electron beam exposure. After the EBL write was complete, the sample was removed and processed for the development of patterned features. The samples were developed in a 1:3 methyl isobutyl ketone (MIBK): isopropyl alcohol (IPA) solution for 140 s and rinsed by pure IPA for 20 s, followed by a deionized (DI) water rinse for 20 s. Since a positive photo resist was used, the areas exposed to electron beam and developed were selectively removed. A Trion technology phantom II RIE was used to remove the oxide through the patterned features. The RIE process involved etching SiO₂ using CF₄ (45 sccm) and O₂ (5 sccm) through patterned holes. Once the pattern was transferred to the substrate, PMMA resist was removed by dissolution in acetone and immediately loaded in MBE chamber for the nanowire growth.

### Example 1

### Preparation of GaAs/GaAs_{(1-x-y)}SbₓN_{y}/GaAs Core-Shell Nanowires

In one exemplary embodiment, core-shell nanowires described herein were prepared as follows. First, Si (111) substrates were chemically treated before loading into the MBE chamber. Substrate surface preparation consisted of complete removal of the native oxide by using a Piranha/HF solution followed by oxidation at room temperature. The thickness of native oxide on Si (111) substrate was controlled by oxidation time. The preferred oxide layer thickness as determined from ellipsometry was found to be approximately 9.1±2 Å for highly dense and vertical nanowires.

To grow GaAs/GaAsSb/GaAs core-shell nanowires, core GaAs nanowires were grown by the vapor-liquid-solid (VLS) mechanism. A substrate growth temperature of 620° C. was used and Ga-assisted self-catalyzed growth was initiated by opening the Ga flux prior to the As₄ flux. The tetramer As₄ source led to the growth of nanowires of uniform diameter, in contrast to tapered nanowires, which were observed with the use of a cracked As₂ source. Ga-assisted NW growth was initiated by opening the Ga shutter for 15 seconds prior to the opening of As₄ flux. Ga flux used corresponded to a nominal GaAs layer growth rate of 0.7 monolayer/second. The core GaAs NW growth duration was approximately 10 min.

After core GaAs NW growth, the Ga droplets on the tips of the nanowires were solidified by closing the Ga shutter and allowing high As₄ flux for 10 minutes, thereby preventing axial growth during the subsequent shell growth. The GaAsSbN shell was then grown around the GaAs core using the so-called vapor solid (VS) mechanism. The GaAsSbN shell growth was initiated at 540° C. by opening the Sb and N shutters. A constant Sb BEP of 1.4×10⁻⁶ Torr was used for the three different samples under investigation while the N beam equivalent pressures were set at 0 Torr, 8.5×10⁻⁸ Torr, and 1.8×10⁻⁷ Torr. The first shell growth duration was approximately 10 min. Both Sb and N shutters were closed for the growth of final GaAs shell at 540° C. The second (GaAs) shell growth duration was approximately 5 min. The substrate was held stationary for all the growths.

### Example 2

### Preparation of GaAs/GaAs_{(1-x-y)}SbₓN_{y}/GaAs Core-Shell Nanowires

In another exemplary embodiment, the growth of dilute nitride GaAs/GaAsSbN/GaAs core-shell nanowires was carried out on chemically cleaned (piranha/HF) p-type Si (111) substrates by plasma assisted MBE. The growth included three steps. First, core GaAs nanowires were grown by the vapor-liquid-solid (VLS) mechanism with Ga as a catalyst at about 620° C. while maintaining the As₄ flux with a beam equivalent pressure of about 4.8×10⁻⁶ Torr. The shell growth was initiated by lowering the growth temperature to about 540° C. and opening the Ga, Sb and N shutters. A constant Sb flux of about 1.4×10⁻⁶ Torr was used for three different samples under investigation while the N flux was set at about 0 Torr, 8.5×10⁻⁸ Torr (1.7% flux) and 1.8×10⁻⁷ Torr (3.7% flux). These three samples are referred to, respectively, as reference (or “without N”), LN and HN samples. Both Sb and N shutters were closed for the growth of final GaAs shell around the GaAsSbN shell.

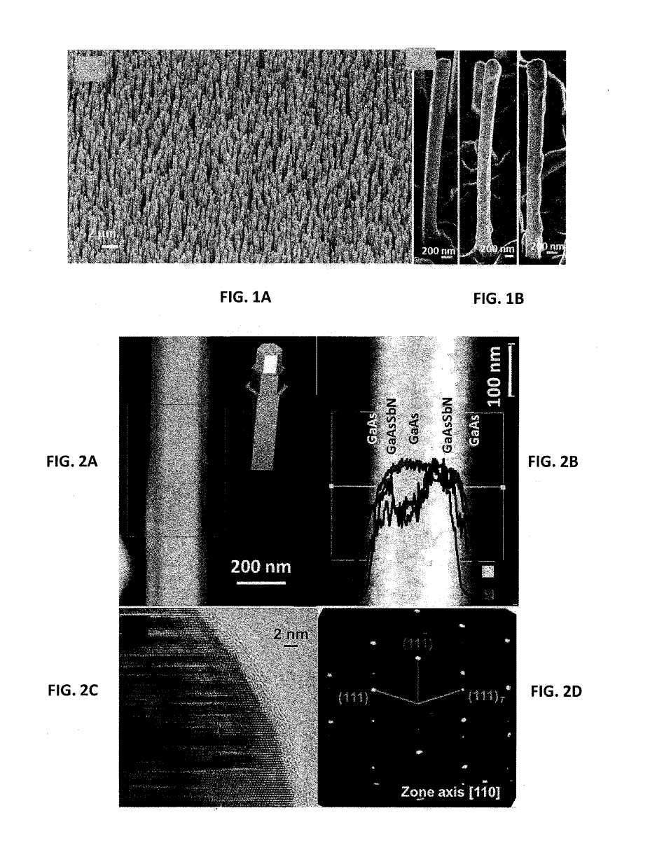

FIG. 1A shows the 45° tilted scanning electron microscope (SEM) image of highly vertical GaAs/GaAsSbN/GaAs nanowires. The nanowires were approximately 4 μm long with a core diameter of approximately 80 nm. The GaAsSbN and outer GaAs shells were approximately 70 nm and 20 nm thick, respectively. The reference GaAsSb nanowires exhibited smooth and well defined hexagonal facets in contrast to the corrugated side facets observed in the dilute nitride nanowires (FIG. 1B; from left to right, the NWs are reference, LN, and HN). Also, the radial growth rate increased from 0.78 Å/s for GaAsSb core-shell nanowires to 1.4 Å/s for GaAsSbN core-shell nanostructures. Not intending to be bound by theory, this increased growth rate can be explained by a Sb—N exchange mechanism, in which N readily occupies the Group V lattice site due to a Sb kick-out mechanism; it is believed that the smaller size of N relieves the strain. Further, as N diffuses inwards, Sb coverage on the growth front is expected to increase due to the N kicking out Sb to the surface, which is likely to alter the surface energy. Enhancement in growth rate in dilute nitride nanowires is observed. The HN nanowires exhibit more regularly spaced sawtooth-faceted sidewalls (FIG. 1B).

FIG. 2A displays a high-angle annular dark-field (HAADF) STEM image of a typical GaAs/GaAsSbN/GaAs core-shell nanowire. EDS compositional mapping of the nanowire confirms the shell structure (FIG. 2B). The high resolution TEM (HR-TEM) image (FIG. 2C) and selected-area electron diffraction (SAED) pattern (FIG. 2D) confirm the zinc-blende (ZB) structure of the nanowire. The presence of twins and stacking faults (FIG. 2C) further attest to the saw-tooth faceted nanowire morphology displayed by these nanowires.

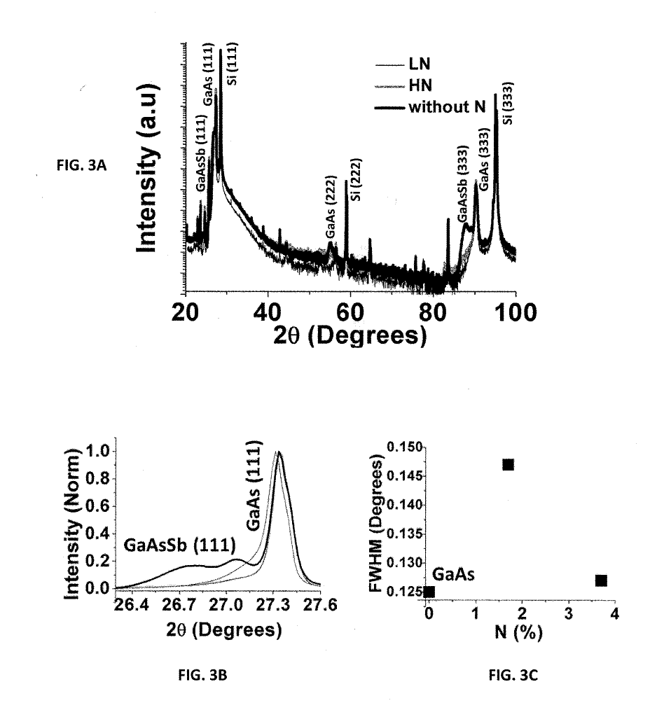

FIG. 3A shows the x-ray diffraction patterns of GaAs/GaAsSbN/GaAs nanowires with varying N content. The presence of only GaAs(111), Si(111) and their higher order Bragg peaks attest to highly vertical <111> oriented nanowires. The GaAsSbN nanowires exhibit peaks corresponding to (111) GaAs (FIG. 3B). The shift of Bragg angle from lower to higher values is evidence of the strain compensation by N leading to an x-ray signature that is closely lattice matched to the GaAs peak. Further, the decreased FWHM with increasing N content (FIG. 3C) corroborates the strain relieving effect in the GaAsSb lattice due to the addition of N. The FWHM of the GaAs (111) peak in the HN sample is close to that of GaAs, which reveals lattice matching of GaAsSbN to GaAs with good crystalline quality.

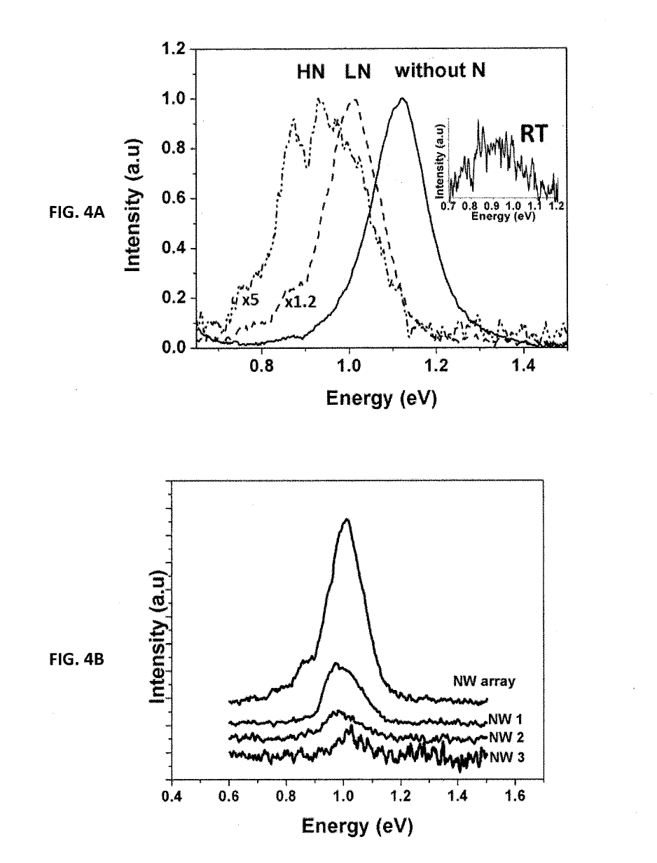

FIG. 4A displays the normalized 4K micro-photoluminescence (PL) spectra of as-grown nanowires as a function of N content. The dilute nitride nanowires exhibit a red shift with respect to the GaAsSb nanowire PL peak energy, and the shift increases with increasing N content. Not intending to be bound by theory, this result is attributed to lowering of the conduction band, manifesting in the reduction of the band gap. The data show an increasing red shift with increasing N flux. The PL intensity decreases with increasing N content, as is evident from the noisy spectra observed for HN nanowires. The suppression of intensity might be attributed to N related defects and non-radiative centers created by the addition of N to the GaAsSb lattice. The lower energy peak at approximately 0.87 eV in the PL spectra of both LN and HN samples can be attributed to N-induced defect level, and the relative intensity of this peak increases with increasing N content. These unannealed HN nanowires exhibit room temperature PL emission at 1.3 μm with a quantum efficiency estimated to be approximately 20% (inset in FIG. 4A). As shown in FIG. 4B, good compositional homogeneity amongst the nanowires was evidenced by the replication of 4K PL spectra of the nanowire array by its single nanowire counterpart, with a similar FWHM of 150 meV.

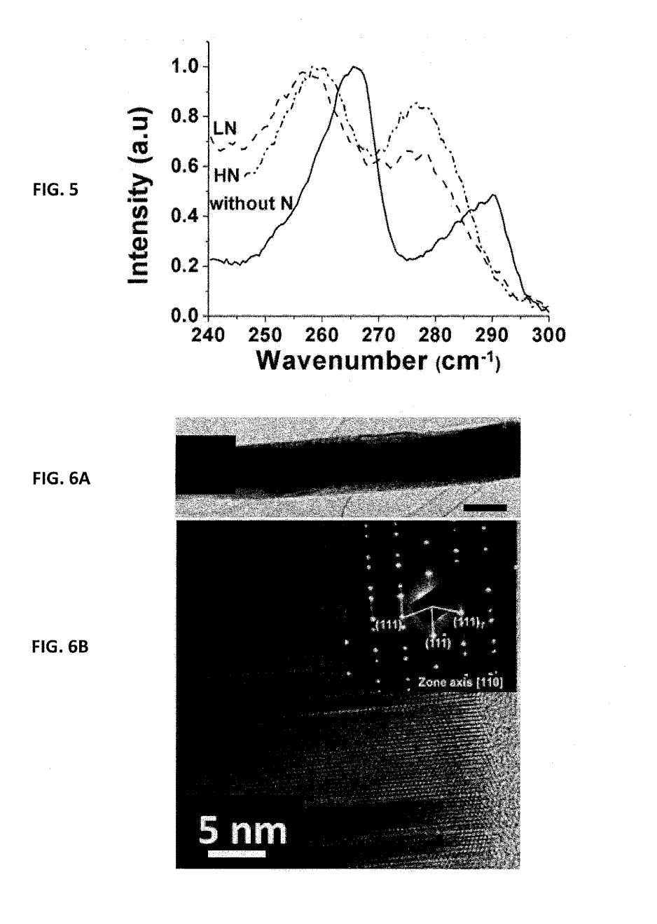

FIG. 5 is a comparison of the room temperature Raman spectra of GaAs/GaAsSbN/GaAs nanowires with the reference GaAsSb nanowires. The Raman spectrum of reference GaAs/GaAsSb/GaAs nanowires is highly asymmetric and display LO and TO modes at 290.3 cm⁻¹ and 265.6 cm⁻¹, respectively, which correspond to the ZB structure. A symmetric line shape and large redshifts in both LO and TO modes to 278.7 cm⁻¹ and 257.2 cm⁻¹, respectively, are observed in the dilute nitride nanowires. There are various mechanisms that can induce red shifts in the Raman spectra: (i) alloying, (ii) strain, (iii) alloy disorder, (iv) laser heating, (v) phonon confinement, and (vi) phonon localization at the defects. It was observed that both LN and HN display LO at 278.7 cm⁻¹. Strain in the nanowires is sufficiently small, as evidenced by the XRD spectra. A symmetric line shape of the phonon modes and absence of any disorder activated phonon modes at lower phonon frequency suggest compositional disorder is unlikely. Laser intensity variation of the Raman signal was carried out; however, the phonon modes in both the GaAsSb and GaAsSbN nanowires exhibited the same red shift of approximately 4 cm⁻¹ on increasing the laser intensity by 100 fold. The phonon confinement has inverse dependence on the diameter, the nitride nanowires being larger in diameter than the reference non-nitride nanowires; thus, the phonon confinement is expected to be weaker in the GaAsSbN nanowires than in the GaAsSb nanowires.

TEM investigation revealed the presence of planar defects, namely, stacking faults and twins in dilute nitride nanowires. The nanowires disclosed in this Example heretofore were not intentionally annealed, and point defects are likely to be present, thus contributing to the observed red shift. Rapid thermal annealing (RTA) of these nanowires was thus carried out (700° C. for 30 sec) to test this hypothesis. Indeed, the Raman signal approached closer to that of the GaAsSb nanowires and was accompanied with the transformation from a symmetric to asymmetric line shape, which is characteristic of the dominance of planar defects over point defects. Hence, the perturbation of the phonon propagation due to the point defects appears to be a contributor to the observed large red shift in the Raman spectra of dilute nitride nanowires described herein.

As noted above, these dilute nitride nanowires were not intentionally annealed. Room temperature PL from as-grown dilute nitride thin films has not been reported. The dilute nitride nanowires exhibit planar defects, namely, stacking faults and twins, in addition to the point defects as evidenced by TEM and Raman analysis, respectively. The carriers are confined laterally in nanowires. Further, during the PL measurement, evidence of laser heating was observed, with the nanowire becoming smaller in length. Thus it is possible that laser induced annihilation of the defects may occur. Without being bound by theory, it is thought that all the above contribute to a reduction in the density of non-radiative recombination centers in the nanowire configuration, enabling observation of room temperature PL.

Thus, 1.3 μm PL emission in dilute nitride GaAs/GaAsSbN/GaAs core-shell nanowires is disclosed herein. The 4K PL spectrum of a single nanowire corresponds well to the spectrum of the array, indicating good homogeneity. Close lattice matching of the x-ray peak to GaAs and the red shift of the PL are believed to be indications of N incorporation in the nanowires. Large red shift in Raman optical phonon modes has been found and may be caused by the phonon localization at the defects. The decreased strain in the nanowires leading to the growth of straight vertical nanowires can be advantageous for devices. The observation of room temperature PL in these nanowires is advantageous, and ex situ annealing further improves the quality.

### Example 3

### Characterization of GaAs/GaAs_{(1-x-y)}SbₓN_{y}/GaAs Core-Shell Nanowires

As described above, introduction of very low nitrogen concentrations into a Group III-V material system is sufficient to modulate the band gap over a wide range. Herein is presented the effects of ex-situ RTA on the optical properties of GaAs/GaAsSbN/GaAs nanowires grown by self-catalyzed MBE. Various characterization techniques, namely, TEM, low temperature μ-PL, Raman spectroscopy and current (I)-voltage (V) measurements were used to ascertain the nature of defects being annihilated. Temperature dependent PL was also examined, in part to understand the effects of localized states and recombination mechanisms.

FIG. 6A displays a bright field TEM image of a post growth GaAs/GaAsSbN/GaAs core-shell NW annealed at 750° C. The HR-TEM image and associated SAED pattern confirm the ZB structure of the NW (FIG. 6B). The existence of twins and stacking faults in these nanowires indicated that annealing does not affect the planar defects present in the as-grown nanowires as described above. Since it is difficult to assess the presence/absence of point defects solely using TEM, any inference on their relevance must be based on indirect evidence provided by different techniques, namely, PL, Raman and I-V measurements as discussed below.

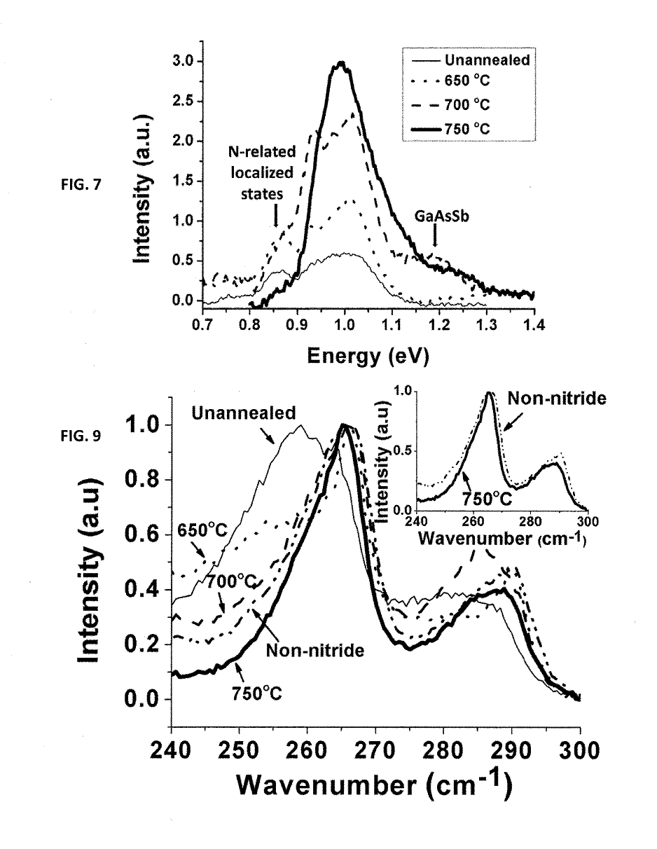

FIG. 7 shows the 4K PL spectra of GaAs/GaAsSbN/GaAs core-multi shell nanowires annealed at different temperatures, namely, 650° C., 700° C., and 750° C., as compared with unannealed nanowires. The Sb composition in the nanowires is approximately 10 at. %, based on EDS. As-grown unannealed nanowires exhibit two characteristic PL peaks at approximately 0.99 eV and approximately 0.85 eV that are associated with the band to band transition and band tailing, respectively, in dilute nitride III-V system.

Contributors to band tail induced states include compositional fluctuations, localized defect states, and inhomogeneous lattice deformation. With increasing annealing temperature, the intensity of band to band emission increases by five-fold with a corresponding decrease in the FWHM of the PL peak, while the intensity of the N-related defect peak at 0.85 eV gradually diminishes. This latter peak ultimately vanishes for nanowires annealed at 750° C. Not intending to be bound by theory, these results are believed to be signatures for annihilation of N-related defects, which results from significant reduction in the density of recombination centers responsible for non-radiative processes. It is further believed that suppression of these non-radiative centers facilitates PL emission from higher energy states, which leads to increased PL intensity with increasing annealing temperature. An emission peak at 0.93 eV is also observed in all the samples, including unannealed samples. Again not intending to be bound by theory, it is believed that this result is related to compositional fluctuations originating from N incorporation as it merges with the band-band peak for nanowires annealed at 750° C. In addition, an evolution of a distinct PL peak at 1.2 eV at 700° C. which becomes a hump at higher annealing temperature of 750° C. is believed to correspond to a band to band transition of the host non-nitride composition of GaAsSb with 10 at. % of Sb.

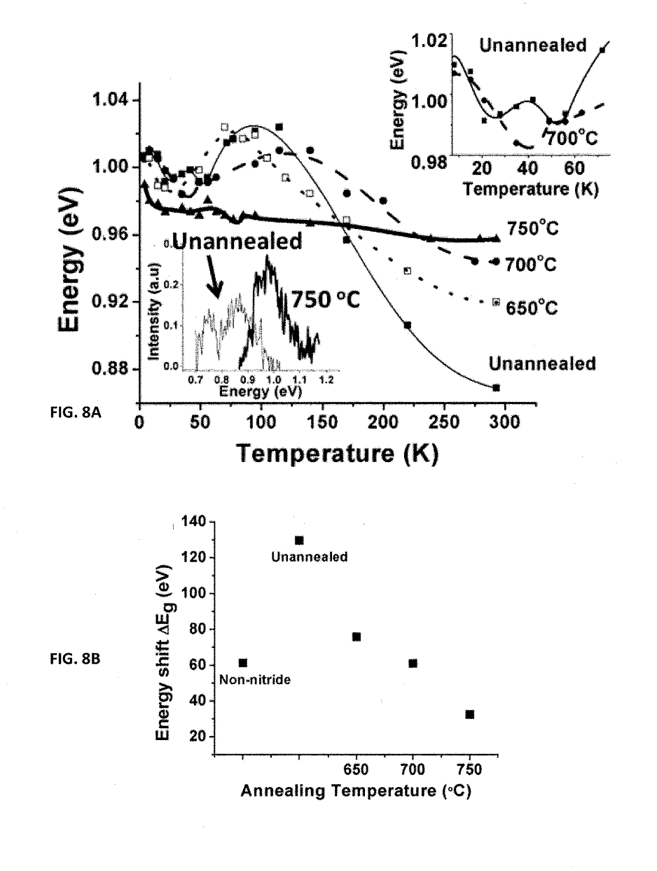

Temperature dependence of PL emission was studied for all samples, as shown in FIG. 8A, to achieve a better understanding of N induced localized states and recombination mechanisms. All nanowires exhibit the characteristic red-blue-red shift in PL peak energy with temperature, which is known as “S-Curve” behavior (FIG. 8A). This behavior is attributed to exciton localization in band tail states due to potential fluctuations. For T<100K, radiative recombination is largely determined by localized excitons, with free carrier recombination becoming dominant for T>100K. Not intending to be bound by theory, this effect can be explained as follows.

In the low temperature regime, with rising temperature the excitons confined in the local potential minimum obtain sufficient thermal energy to surmount small barriers and thus relax to lower energy states. The recombination of these excitons is responsible for the reduced PL emission energy. With an increase in temperature, the excitons gain sufficient energy to populate the higher energy band tail states, and the recombination from these states is attributed to the observed blue shift in the band gap. For temperatures in the region of 75 K to 140 K, depending on the sample, corresponding to the highest PL peak energy, the excitons are delocalized. Beyond this temperature, free carrier recombination dominates, and the regular temperature induced band gap shrinkage occurs due to the electron-phonon interaction and lattice relaxation. Although the overall temperature behavior of the PL in thin films and nanowires is the same, in the nanowires an additional red-blue shift is observed around 50 K. Such an additional feature is often reported to be due to splitting of the heavy hole (HH) and light hole (LH) leading to the corresponding excitonic transitions. However, the PL spectra shown in FIG. 7 did not exhibit any distinct peaks that would correspond to LH and HH transitions. XRD patterns of the annealed GaAsSbN nanowires (not shown here) exhibited only a (111) GaAs peak and did not exhibit any other distinct peak for as-grown nitride core shell nanowires. This can be considered as evidence of a lattice matched GaAs/GaAsSbN/GaAs core-shell structure, which suggests that any contribution of a strain component to the splitting of HH and LH is negligible. Therefore, not intending to be bound by theory, the additional low temperature feature is assigned to the differences in the electron-phonon interaction with the HH and LH excitons becoming more pronounced for lower dimensional structures, although the energy splitting between HH and LH excitons may be small.

The pronounced S-curve for unannealed nanowires and nanowires annealed at 650° C. suggest a strong localization energy, which is measured to be 31-42 meV. The localization energy reduces to 18.6 meV and 8 meV with increasing annealing temperature to 700° C. and 750° C., respectively, which is indicative of efficient annihilation of band tail states leading to decreased potential fluctuations. This is also further supported by the increase in the PL intensity and narrowing of the FWHM of the PL spectra (FIG. 7). Another dramatic change that is observed with increasing annealing temperature is a reduction in the energy shift between 4K and 300K, ΔE_{g} (4K-300K), 129 meV for unannealed nanowires to 32.4 meV for the samples annealed at 750° C., as shown in FIG. 8B. In unannealed samples and at the lower annealing temperature of 650° C., the localized N level is coupled with extended states of the conduction band (CB). This can be described by a band anti-crossing (BAC) model and exhibits the characteristic temperature induced band gap shrinkage. In the annealed nanowires where the band states are efficiently annihilated, the temperature independent characteristic of the N level prevails. The room temperature PL of these samples are in the 1.3 μm region (FIG. 8A, inset), a wavelength of great interest for photonic integrated circuits.

FIG. 9 displays the Raman spectra of annealed samples and compared to the reference as-grown nanowires. The Raman spectrum of as-grown dilute nitride nanowires is broader and exhibits a large red shift of 7 cm⁻¹ compared to that of reference non-nitride nanowires. The origin of this red shift is attributed to phonon localization at point defects. The line shape is also more symmetric for as-grown nanowires. On annealing, the Raman signal reverts back to the reference Raman spectra for non-nitride GaAsSb nanowires and even exhibits the asymmetric line shape. For 750° C. annealed nanowires, the FWHM is also reduced. The change in line shape is representative of the dominance of planar defects over point defects. Thus, Raman data provides additional strong evidence for annihilation of the point defects on annealing.

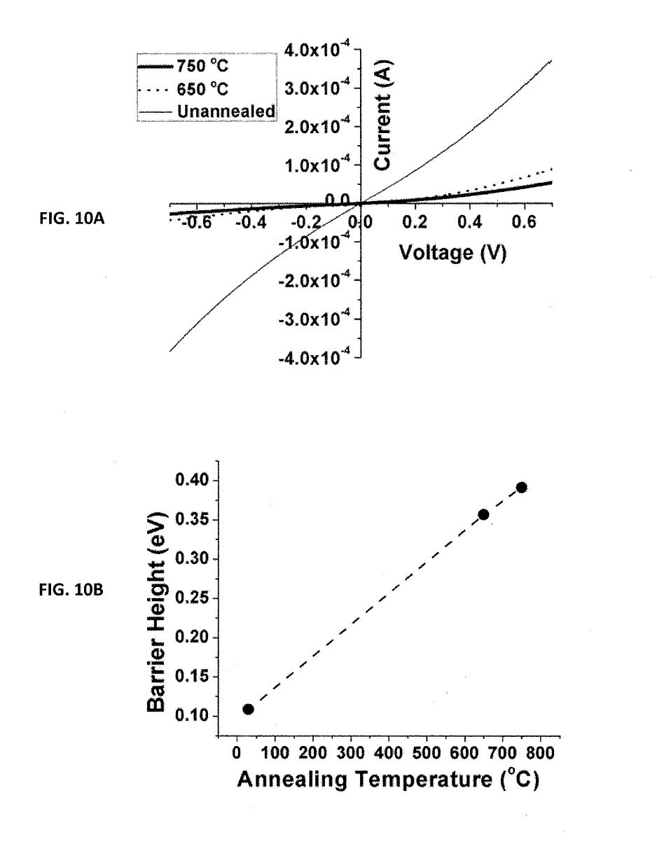

Finally, current-voltage (I-V) measurements were also conducted to provide more insight into the nature of the defects annihilated. FIG. 10A displays I-V measurements on ensembles of nanowires annealed at different temperatures. The I-V characteristic is symmetric around the origin and for a given voltage, nanowires annealed at 750° C. exhibit the lowest current compared to unannealed nanowires and nanowires annealed at 650° C. Assuming the two contacts at the two ends of the nanowires to be Schottky contacts, the barrier height at these contacts have been determined by best fit to the experimental I-V curve using a Matlab based program applied to a metal-semiconductor-metal (M-S-M) model (See Liu, Y., et al., Quantitative fitting of nonlinear current—voltage curves and parameter retrieval of semiconducting nanowire, nanotube and nanoribbon devices. Journal of nanoscience and nanotechnology, 2008. 8(1): p. 252-258 and Zhang, Z., et al., Quantitative analysis of current—voltage characteristics of semiconducting nanowires: decoupling of contact effects. Advanced functional materials, 2007. 17(14): p. 2478-2489). As shown in FIG. 10B, the barrier height increases from approximately 0.1 eV to 0.4 eV with increasing annealing temperature, from room temperature to 750° C., respectively. The increase in the barrier height with annealing indicates that charge transfer at the metal-semiconductor interface for as-grown nanowires is due to trap-assisted tunneling. Further, a high concentration of point defects associated with shallow donors also promotes enhanced electrical transport. Thus, higher electrical conduction can be viewed as evidence for the presence of a high point defect density in the nanowires. Therefore, the I-V characteristics provide additional support for point defect annihilation in the 750° C. annealed nanowires, which is consistent with the PL and Raman results discussed earlier. Generally, dilute nitrides exhibit lower Schottky barrier heights due to the effects of interface states, series resistance, tunneling process and non-uniformity distribution of the interfacial charge. Depending on the density of the defects at the metal-semiconductor interface and contact material work function, the Schottky barrier height can vary from 0.36-0.95 eV.

The effect of ex-situ annealing of GaAs/GaAsSbN/GaAs core-multi shell nanowires in a N₂ ambient has been disclosed. 4K μ-PL spectra of the unannealed nanowires displayed a peak at approximately 0.99 eV with a shoulder at lower energy attributed to band tail states. Raman spectra of as-grown dilute nitride nanowires exhibited a red shift of 7 cm⁻¹ and were broadened in comparison to that of reference non-nitride nanowires, confirming phonon localization at N-induced localized defects. RTA of these nanowires in an N₂ atmosphere was employed to annihilate various N-induced defects. With increase in annealing temperature from 650 to 750° C., the PL peak at lower energy corresponding to band tail states vanishes and the Raman spectra reverted back towards the reference spectra, evidence of annihilation of N-related defects. Significant increase in the Schottky barrier height of the nanowires annealed at elevated temperature further supports this inference. The temperature dependent PL spectra exhibited the well-known “S-curve” behavior, a characteristic of dilute nitride material systems and a signature of exciton localization. Further, room temperature emission and suppression of the temperature induced band gap in the annealed nanowires are attractive attributes offered by these dilute nitride nanowires towards nanoscale optoelectronic device applications.

It will be understood that various details of the presently disclosed subject matter may be changed without departing from the scope of the presently disclosed subject matter. Furthermore, the foregoing description is for the purpose of illustration only, and not for the purpose of limitation.

1. A composition comprising:
one or more core-shell nanowires comprising a core and a first shell surrounding or substantially surrounding the core,
wherein the core is formed from GaAs;
wherein the first shell is formed from GaAs_{(1-x-y)}SbₓN_{y};
wherein x is 0.08-0.15;
wherein y is 0.005-0.035; and
wherein the nanowires have an average emission maximum of 1.25-1.35 μm.

2. The composition of claim 1, wherein x is 0.10-0.17.

3. The composition of claim 1, wherein y is 0.01-0.02.

4. The composition of claim 1, wherein the nanowires further comprise a second shell surrounding or substantially surrounding the first shell, and the second shell is formed from GaAs.

5. The composition of claim 1, wherein the nanowires have the structure GaAs/GaAs_{(0.82-0.9)}Sb_{(0.09-0.15)}N_{(0.005-0.033)}/GaAs.

6. The composition of claim 1, wherein the core has an average diameter greater than the Bohr diameter of GaAs.

7. The composition of claim 1, wherein the core has an average diameter of 50-110 nm.

8. The composition of claim 1, wherein the core has an average diameter of 70-90 nm.

9. The composition of claim 1, wherein the first shell has an average thickness greater than the Bohr diameter of GaAs_{(1-x-y)}SbₓN_{y}.

10. The composition of claim 1, wherein the first shell has an average thickness of 30-90 nm.

11. The composition of claim 1, wherein the first shell has an average thickness of 50-80 nm.

12. The composition of claim 1, wherein the first shell has an average thickness less than or equal to the Bohr diameter of GaAs_{(1-x-y)}SbₓN_{y}.

13. The composition of claim 1, wherein the first shell has an average thickness of less than 10 nm.

14. The composition of claim 4, wherein the second shell has an average thickness of at least 5 nm.

15. The composition of claim 4, wherein the second shell has an average thickness of 10-30 nm.

16. The composition of claim 1, wherein the nanowires have an average length of at least 2 μm.

17. The composition of claim 1, wherein the nanowires have a straight or substantially straight morphology.

18. The composition of claim 1, wherein the nanowires have an average length of at least 2 μm, an average aspect ratio of at least 10, and an average radius of curvature of at least 5 times the average length of the core-shell nanowires.

19. The composition of claim 1, wherein the nanowires have a room temperature photoluminescence quantum yield of at least 10%.

20. The composition of claim 1, wherein the nanowires are formed by molecular beam epitaxy.
